(19) United States
(12) Patent Application Publication
(10) Pub. No.: US 2026/0039094 A1
(43) Pub. Date: Feb. 5, 2026

(54) LASER MODULE AND LASER PROCESSING MACHINE

(71) Applicant: SEIKO EPSON CORPORATION, Tokyo (JP)

(72) Inventors: Eiji MORIKUNI, MATSUMOTO-SHI (JP); Masamitsu MOCHIZUKI, CHINO-SHI (JP)

(73) Assignee: SEIKO EPSON CORPORATION, Tokyo (JP)

(21) Appl. No.: 19/284,649

(22) Filed: Jul. 29, 2025

(30) Foreign Application Priority Data
Jul. 30, 2024 (JP) 2024-123383

(51) Int. Cl. H01S 5/40; H01S 5/02253; H01S 5/02255; H01S 5/11; H01S 5/42

(52) U.S. Cl. CPC H01S 5/4012; H01S 5/02253; H01S 5/02255; H01S 5/42; H01S 5/11

(57) ABSTRACT

A laser module that includes a first substrate, a first semiconductor laser light source provided at the first substrate and emitting a first beam in a first direction inclined at a first angle larger than 0° and smaller than 90° with respect to a first perpendicular line of an emission surface, a second semiconductor laser light source provided at the first substrate and emitting a second beam in the first direction, a first mirror provided parallel to the first perpendicular line and configured to reflect the first beam emitted in the first direction, a second mirror configured to transmit the first beam reflected by the first mirror in a second direction different from the first direction and reflect the second beam in the second direction, and a light condensing optical system condensing the first beam and the second beam from the second mirror.

The present application is based on, and claims priority from JP Application Serial Number 2024-123383, filed Jul. 30, 2024, the disclosure of which is hereby incorporated by reference herein in its entirety.

### BACKGROUND

### 1. Technical Field

The present disclosure relates to a laser module and a laser processing machine.

### 2. Related Art

A laser module is known that multiplexes beams from a plurality of semiconductor laser light sources and emits the multiplexed beams in order to achieve a high output.

For example, JP 2000-141757 A describes a light beam exposure apparatus including a plurality of light source units having different wavelength characteristics, a dichroic mirror that multiplexes light beams having different wavelength characteristics respectively emitted from the plurality of light source units, and an imaging optical system that irradiates an exposure surface with the light beams from the dichroic mirror.

In the light beam exposure apparatus described in JP 2000-141757 A, the plurality of light source units emit light beams in a perpendicular line direction of an emission surface and are provided in a stepwise manner so as to make optical path lengths uniform. For this reason, the apparatus becomes large.

### SUMMARY

An aspect of a laser module according to the present disclosure includes
a first substrate,
a first semiconductor laser light source provided at the first substrate and configured to emit a first beam in a first direction inclined at a first angle larger than 0° and smaller than 90° with respect to a first perpendicular line of an emission surface,
a second semiconductor laser light source provided at the first substrate and configured to emit a second beam in the first direction,
a first mirror provided parallel to the first perpendicular line and configured to reflect the first beam emitted in the first direction from the first semiconductor laser light source,
a second mirror configured to transmit the first beam reflected by the first mirror in a second direction different from the first direction and reflect the second beam emitted from the second semiconductor laser light source in the second direction, and
a light condensing optical system configured to condense the first beam and the second beam from the second mirror.

An aspect of a laser processing machine according to the present disclosure includes
the laser module.

### BRIEF DESCRIPTION OF THE DRAWINGS

FIG. 1 is a diagram schematically illustrating a laser module according to the embodiment.

FIG. 2 is a diagram schematically illustrating the laser module according to the embodiment.

FIG. 3 is a cross-sectional view schematically illustrating a first semiconductor laser light source of the laser module according to the embodiment.

FIG. 4 is a diagram schematically illustrating a laser module according to a first modification of the embodiment.

FIG. 5 is a cross-sectional view schematically illustrating a first semiconductor laser light source and a position adjustment mechanism of the laser module according to the first modification of the embodiment.

FIG. 6 is a diagram schematically illustrating the first semiconductor laser light source and the position adjustment mechanism of the laser module according to the first modification of the embodiment.

FIG. 7 is a diagram schematically illustrating a laser module according to a second modification of the embodiment.

FIG. 8 is a diagram schematically illustrating the laser module according to the second modification of the embodiment.

FIG. 9 is a perspective view schematically illustrating a laser module according to a third modification of the embodiment.

FIG. 10 is a diagram schematically illustrating a laser module according to a fourth modification of the embodiment.

FIG. 11 is a diagram schematically illustrating the laser module according to the fourth modification of the embodiment.

FIG. 12 is a diagram schematically illustrating a laser module according to a fifth modification of the embodiment.

FIG. 13 is a diagram schematically illustrating the laser module according to the fifth modification of the embodiment.

FIG. 14 is a diagram schematically illustrating a laser module according to a sixth modification of the embodiment.

FIG. 15 is a diagram schematically illustrating a laser module according to a seventh modification of the embodiment.

FIG. 16 is a diagram schematically illustrating a laser processing machine according to the embodiment.

### DESCRIPTION OF EMBODIMENTS

A preferred embodiment of the present disclosure is described in detail below with reference to the drawings. The embodiment to be described below does not unduly limit the content of the present disclosure described in the claims. In addition, not all the configurations described below are essential constituent elements of the present disclosure.

### 1. Laser Module

### 1.1. Overall Configuration

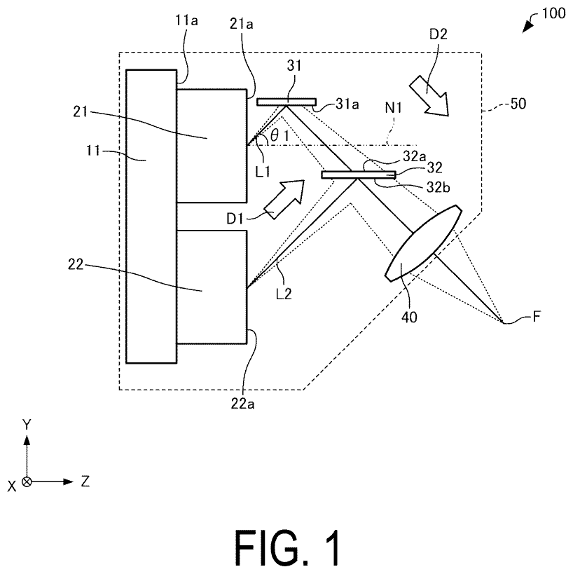

First, a laser module according to the embodiment will be described with reference to the drawings. FIG. 1 is a diagram schematically illustrating a laser module 100 according to the embodiment. Note that, an X-axis, a Y-axis, and a Z-axis are illustrated in FIG. 1 as three axes orthogonal to each other.

As illustrated in FIG. 1, the laser module 100 includes, for example, a first substrate 11, a first semiconductor laser light source 21, a second semiconductor laser light source 22, a first mirror 31, a second mirror 32, a light condensing optical system 40, and a housing 50. Note that for the sake of convenience, in FIG. 1, illustration is given through the housing 50.

The first substrate 11 supports the first semiconductor laser light source 21 and the second semiconductor laser light source 22. The first substrate 11 includes a first plane 11a. The first plane 11a is a flat surface. The first substrate 11 is, for example, a copper substrate, a silicon substrate, or the like. The first substrate 11 dissipates heat generated in the semiconductor laser light sources 21 and 22.

The first semiconductor laser light source 21 is provided at the first plane 11a of the first substrate 11. The first semiconductor laser light source 21 is directly provided at the first plane 11a, for example. The first semiconductor laser light source 21 includes an emission surface 21a that emits light. In the illustrated example, the emission surface 21a is parallel to the plane 11a. A first perpendicular line N1 of the emission surface 21a is parallel to the Z-axis. The emission surface 21a is a surface of the first semiconductor laser light sources 21 on an opposite side to the first substrate 11.

The first semiconductor laser light source 21 emits a first beam L1. To be specific, the first semiconductor laser light source 21 emits the first beam L1 in a first direction D1 inclined at a first angle θ1 with respect to the first perpendicular line N1. Here, “emitting light in an A direction” means emitting light such that an optical axis of the light is in the A direction. Similarly, “transmitting light in the A direction” and “reflecting light in the A direction” mean transmitting and reflecting the light such that an optical axis of the light is in the A direction, respectively. “An optical axis of light” refers to a light beam passing through a center of the light condensing optical system 40 in a light flux. The first angle θ1 is an angle larger than 0° and smaller than 90°, for example, from 15° to 75°, and may be from 30° to 60°. In the illustrated example, the first angle θ1 is 45°.

The second semiconductor laser light source 22 is provided at the first plane 11a of the first substrate 11. The second semiconductor laser light source 22 is directly provided at the first plane 11a, for example. In the illustrated example, the semiconductor laser light sources 21 and 22 are arranged in the Y-axis direction. The emission surface 21a of the first semiconductor laser light source 21 and an emission surface 22a of the second semiconductor laser light source 22 are located at the same plane.

The second semiconductor laser light source 22 emits a second beam L2. To be specific, the second semiconductor laser light source 22 emits the second beam L2 in the first direction D1 inclined at the first angle θ1 with respect to the first perpendicular line N1. An optical axis of the first beam L1 emitted from the first semiconductor laser light source 21 and an optical axis of the second beam L2 emitted from the second semiconductor laser light source 22 are parallel to each other. Each of the semiconductor laser light sources 21 and 22 is, for example, a photonic crystal surface emitting laser (PCSEL). In the semiconductor laser light sources 21 and 22, by adjusting an arrangement of photonic crystals, light can be emitted in the first direction D1 inclined at the first angle θ1 with respect to the first perpendicular line N1 by composite modulation. A radiation angle of the first beam L1 and a radiation angle of the second beam L2 are, for example, the same as each other. Note that detailed configurations of the semiconductor laser light sources 21 and 22 will be described later.

The first mirror 31 is provided parallel to the first perpendicular line N1. To be specific, the first mirror 31 includes a reflecting surface 31a parallel to the first perpendicular line N1. A perpendicular line of the reflecting surface 31a is orthogonal to the first perpendicular line N1. The first mirror 31 has, for example, a plate shape. The first mirror 31 reflects the first beam L1 emitted in the first direction D1 from the first semiconductor laser light source 21, in the second direction D2 at the reflecting surface 31a. The second direction D2 is a direction different from the first direction D1. In the illustrated example, the first direction D1 and the second direction D2 are directions orthogonal to each other. The first mirror 31 bends the first beam L1 by 90°.

The second mirror 32 is provided parallel to the first perpendicular line N1. To be more specific, the second mirror 32 includes a transmitting surface 32a and a reflecting surface 32b parallel to the first perpendicular line N1. A perpendicular line of the transmitting surface 32a and a perpendicular line of the reflecting surface 32b are orthogonal to the first perpendicular line N1. The transmitting surface 32a and the reflecting surface 32b are surfaces facing away from each other. In the illustrated example, the second mirror 32 is located farther in a +Z-axis direction than the first mirror 31. An optical path length from the first semiconductor laser light source 21 to the second mirror 32 and an optical path length from the second semiconductor laser light source 22 to the second mirror 32 are, for example, the same. The second mirror 32 bends the second beam L2 by 90°.

The second mirror 32 is, for example, a polarization beam combiner (PBC). For example, the semiconductor laser light sources 21 and 22, which are PCSELs, can adjust polarization directions of the beams L1 and L2, respectively, by complex modulation. The polarization directions of the beams L1 and L2 are different from each other. For example, the first beam L1 is P-polarized light, and the second beam L2 is S-polarized light. The beams L1 and L2 enter the second mirror 32 as beams having polarization directions different from each other. The beams L1 and L2 have the same polarization direction when emitted from the semiconductor laser light sources 21 and 22, respectively, but may have polarization directions different from each other when entering the second mirror 32.

The second mirror 32 transmits the first beam L1 reflected by the first mirror 31 in the second direction D2, and reflects the second beam L2 emitted in the first direction D1 from the second semiconductor laser light source 22 in the second direction D2. Then, the second mirror 32 multiplexes the first beam L1 and the second beam L2 and guides the multiplexed beams to the light condensing optical system 40. The first beam L1 reflected by the first mirror 31 enters the second mirror 32 from the transmitting surface 32a, and is emitted from the reflecting surface 32b. The second beam L2 emitted from the second semiconductor laser light source 22 is reflected by the reflecting surface 32b. The second mirror 32 bends the second beam L2 by 90°.

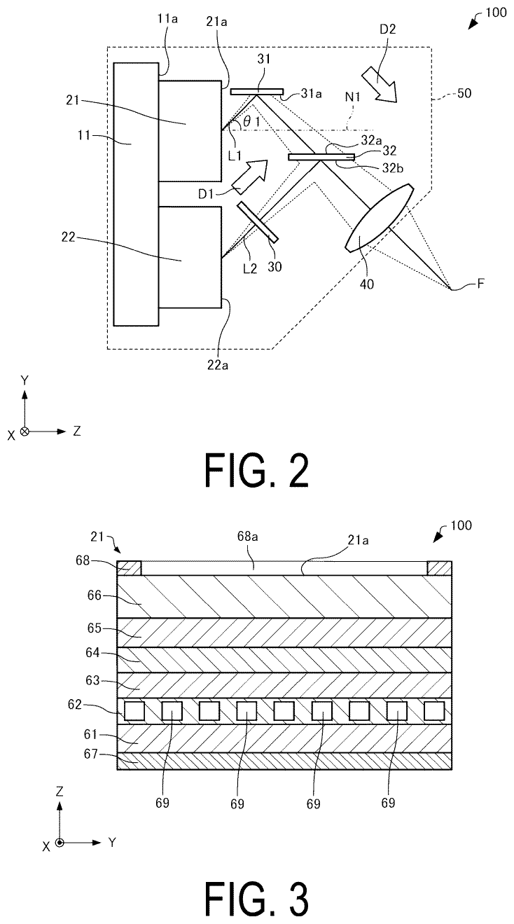

Note that the polarization directions of the first beam L1 emitted from the first semiconductor laser light source 21 and the second beam L2 emitted from the second semiconductor laser light source 22 may be the same as each other. The beams L1 and L2 may be, for example, P-polarized light. In this case, as illustrated in FIG. 2, a λ/2 plate 30 is provided in the optical path from the second semiconductor laser light source 22 to the second mirror 32. The λ/2 plate 30 converts the P-polarized second beam L2 emitted from the second semiconductor laser light source 22 into S-polarized light. Accordingly, the second mirror 32 can multiplex the first beam L1 emitted from the first semiconductor laser light source 21 and the second beam L2 emitted from the second semiconductor laser light source 22.

However, as long as the semiconductor laser light sources 21 and 22 are PCSELs, the polarization of the beams L1 and L2 can be adjusted by complex modulation without using the λ/2 plate 30, and thus the number of components can be reduced, and a size and costs can be reduced.

The first beam L1 and the second beam L2 from the second mirror 32 enter the light condensing optical system 40, as illustrated in FIG. 1. To be specific, the first beam L1 passing through the second mirror 32 and the second beam L2 reflected by the second mirror 32 enter the light condensing optical system 40. The light condensing optical system 40 condenses the beams L1 and L2 from the second mirror 32. In the laser module 100, the beams L1 and L2 can be condensed at a light condensing point F of the light condensing optical system 40 so that light condensing positions and the light condensing angles are made uniform. The light condensing point F is an imaging point of the light condensing optical system 40. Magnifications of a light-source image formed by the first beam L1 and a light-source image formed by the second beam L2 are the same at the light condensing point F. The light condensing optical system 40 is a condensing lens. In the illustrated example, the light condensing optical system 40 is a convex lens.

The housing 50 accommodates the first substrate 11, the semiconductor laser light sources 21, 22, the mirrors 31, 32, and the light condensing optical system 40. A shape and a material of the housing 50 are not particularly limited. Although not illustrated, the housing 50 includes a window portion that transmits the beams L1 and L2 passing through the light condensing optical system 40. The housing 50 can facilitate handling of the laser module 100.

### 1.2. Configuration of Semiconductor Laser Light Source

FIG. 3 is a cross-sectional view schematically illustrating the first semiconductor laser light source 21. As illustrated in FIG. 3, the first semiconductor laser light source 21 includes, for example, a first semiconductor layer 61, a first guide layer 62, a quantum well layer 63, a second guide layer 64, a second semiconductor layer 65, a transparent substrate 66, a first electrode 67, and a second electrode 68. The first semiconductor laser light source 21 and the second semiconductor laser light source 22 basically have structures the same as each other. Therefore, the following description of the first semiconductor laser light source 21 can be applied to the description of the second semiconductor laser light source 22.

The first semiconductor layer 61 is provided between the first electrode 67 and the first guide layer 62. The first semiconductor layer 61 is a semiconductor layer of a first conductivity type. The first semiconductor layer 61 is, for example, a p-type semiconductor layer doped with Mg.

The first guide layer 62 is provided between the first semiconductor layer 61 and the quantum well layer 63. The first guide layer 62 has, for example, a semiconductor superlattice (SL) structure composed of a GaN layer and an InGaN layer, which are an i-type and not intentionally doped with impurities. The numbers of the GaN layers and the InGaN layers composing the first guide layer 62 are not particularly limited.

An opening portion 69 is formed at the first guide layer 62. The opening portion 69 is, for example, a hole. A width of the opening portion 69 is, for example, from 50 nm to 500 nm. A plurality of the opening portions 69 are formed. The plurality of opening portions 69 are periodically arrayed when viewed from the Z-axis direction. The plurality of opening portions 69 are arrayed in, for example, a regular triangular lattice pattern or a square lattice pattern. The plurality of opening portions 69 can exhibit a photonic crystal effect.

The quantum well layer 63 is provided between the first guide layer 62 and the second guide layer 64. The quantum well layer 63 generates light when a current is injected thereinto. The quantum well layer 63 includes, for example, a well layer and a barrier layer. The well layer and the barrier layer are i-type semiconductor layers which are not doped with impurities intentionally. The well layer is, for example, an InGaN layer. The barrier layer is, for example, a GaN layer. The quantum well layer 63 has a multiple quantum well (MQW) structure composed of the well layer and the barrier layer.

Note that the numbers of the well layers and the barrier layers composing the quantum well layer 63 are not particularly limited. For example, only one well layer may be provided, and in this case, the quantum well layer 63 has a single quantum well (SQW) structure.

The second guide layer 64 is provided between the quantum well layer 63 and the second semiconductor layer 65. The second guide layer 64 has, for example, an SL structure composed of a GaN layer and an InGaN layer which are the i-type and not intentionally doped with impurities. The numbers of the GaN layers and the InGaN layers composing the second guide layer 64 are not particularly limited. The first guide layer 62 and the second guide layer 64 have a function of increasing an optical confinement coefficient of the first semiconductor laser light source 21. Note that although not illustrated, the plurality of opening portions 69 need not be provided at the first guide layer 62 and may be provided at the second guide layer 64.

The second semiconductor layer 65 is provided between the quantum well layer 63 and the transparent substrate 66. The second semiconductor layer 65 is a semiconductor layer of a second conductivity type different from the first conductivity type. The second semiconductor layer 65 is, for example, an n-type GaN layer doped with Si. The first semiconductor layer 61 and the second semiconductor layer 65 are clad layers having a function of confining light in the quantum well layer 63.

In the first semiconductor laser light source 21, a pin diode is constituted by the first semiconductor layer 61 of the p-type, the quantum well layer 63 and the guide layers 62 and 64 which are the i-type and not intentionally doped with impurities, and the second semiconductor layer 65 of the n-type. In the first semiconductor laser light source 21, when a forward bias voltage of the pin diode is applied between the first electrode 67 and the second electrode 68, a current is injected into the quantum well layer 63, and electrons and positive holes are recombined in the quantum well layer 63. This recombination causes light emission. The light generated in the quantum well layer 63 propagates in an in-plane direction, forms a standing wave by the photonic crystal effect due to the plurality of opening portions 69, receives a gain in the quantum well layer 63, and performs laser oscillation. Then, the first semiconductor laser light source 21 emits diffracted light as laser light.

The transparent substrate 66 is provided between the second semiconductor layer 65 and the second electrode 68. The transparent substrate 66 transmits light generated in the quantum well layer 63. The transparent substrate 66 is, for example, an n-type semiconductor substrate in which Si is doped.

The first electrode 67 is provided at the first semiconductor layer 61 on an opposite side to the first guide layer 62. The first semiconductor layer 61 may be in ohmic contact with the first electrode 67. The first electrode 67 is electrically coupled to the first semiconductor layer 61. The first electrode 67 is formed by, for example, stacking a Ni layer and an Au layer in this order from the first semiconductor layer 61 side. The first electrode 67 is an electrode on one side for injecting a current into the quantum well layer 63.

The second electrode 68 is provided at the transparent substrate 66 on an opposite side to the second semiconductor layer 65. The transparent substrate 66 may be in ohmic contact with the second electrode 68. The second electrode 68 is electrically coupled to the second semiconductor layer 65 via the transparent substrate 66. The second electrode 68 is formed by, for example, stacking a Cr layer, a Ni layer, and an Au layer in this order from the transparent substrate 66 side. The second electrode 68 is an electrode on another side for injecting a current into the quantum well layer 63.

A through hole 68a is formed at the second electrode 68. Light generated in the quantum well layer 63 is emitted through the through hole 68a. A region of the transparent substrate 66 exposed by the through hole 68a constitutes the emission surface 21a.

As a manufacturing method of the first semiconductor laser light source 21, the semiconductor layers 61, 65, the guide layer 62, 64, and the quantum well layer 63 are formed by epitaxial growth such as a metal organic chemical vapor deposition (MOCVD) method and a molecular beam epitaxy (MBE) method, for example. For example, the opening portion 69 is formed by patterning the first guide layer 62 using an electron beam drawing device. The electrodes 67 and 68 are formed by a sputtering method, a vacuum deposition method, a chemical vapor deposition (CVD) method, or the like. The formed first semiconductor laser light source 21 is mounted in a junction-down manner with the first electrode 67 side facing the first substrate 11 illustrated in FIG. 1, for example.

### 1.3. Effects

The laser module 100 includes the first substrate 11, the first semiconductor laser light source 21 provided at the first substrate 11 and configured to emit the first beam L1 in the first direction D1 inclined at the first angle θ1 larger than 0° and smaller than 90° with respect to the first perpendicular line N1 of the emission surface 21a, the second semiconductor laser light source 22 provided at the first substrate 11 and configured to emit the second beam L2 in the first direction D1, the first mirror 31 provided parallel to the first perpendicular line N1 and configured to reflect the first beam L1 emitted in the first direction D1 from the first semiconductor laser light source 21, the second mirror 32 configured to transmit the first beam L1 reflected by the first mirror 31 in the second direction D2 different from the first direction D1 and reflect the second beam L2 emitted from the second semiconductor laser light source 22 in the second direction D2, and the light condensing optical system 40 configured to condense the first beam L1 and the second beam L2 from the second mirror 32.

Therefore, the laser module 100 can be downsized compared to a case where a plurality of semiconductor laser light sources that emit light in a direction parallel to the first perpendicular line N1 are provided in a stepwise manner, for example. In particular, a size in a direction along the first perpendicular line N1 can be reduced.

Further, in the laser module 100, the semiconductor laser light sources 21 and 22 emit the beams L1 and L2 in the first direction D1, respectively, the first mirror 31 provided parallel to the first perpendicular line N1 reflects the first beam L1 emitted in the first direction D1 from the first semiconductor laser light source 21, the second mirror 32 reflects the first beam L1 reflected by the first mirror 31 and the second beam L2 emitted from the second semiconductor laser light source 22 in the second direction D2, and therefore, the light condensing positions and the light condensing angles of the beams L1 and L2 can be made uniform at the light condensing point F. Accordingly, it is possible to provide the laser module 100 having a high output and a high beam parameter product (BPP).

Furthermore, in the laser module 100, the semiconductor laser light sources 21 and 22 are provided at the same first substrate 11, and thus the semiconductor laser light sources 21 and 22 can be easily adjusted in position and mounted. This makes it possible to reduce costs. Furthermore, since heat generated in the semiconductor laser light sources 21 and 22 can be dissipated by a single first substrate 11, temperature characteristics of the semiconductor laser light sources 21 and 22 can be made uniform. Thus, reliability and stability can be improved.

In the laser module 100, the first beam L1 and the second beam L2 enter the second mirror 32 as beams having polarization directions different from each other, and the second mirror 32 is a polarization beam combiner. Therefore, in the laser module 100, the first beam L1 and the second beam L2 can be multiplexed at the second mirror 32.

In the laser module 100, the first semiconductor laser light source 21 and the second semiconductor laser light source 22 are provided at the first plane 11a of the first substrate 11. Therefore, in the laser module 100, the temperature characteristics of the semiconductor laser light sources 21 and 22 can be made more uniform. Therefore, temperature control for the semiconductor laser light sources 21 and 22 can be easily performed.

In the laser module 100, the first semiconductor laser light source 21 and the second semiconductor laser light source 22 are photonic crystal surface emitting lasers. Therefore, in the laser module 100, the semiconductor laser light sources 21 and 22 can emit the beams L1 and L2, respectively, in the first direction D1 inclined at the first angle θ1 with respect to the first perpendicular line N1.

### 2. Modifications of Laser Module

### 2.1. First Modification

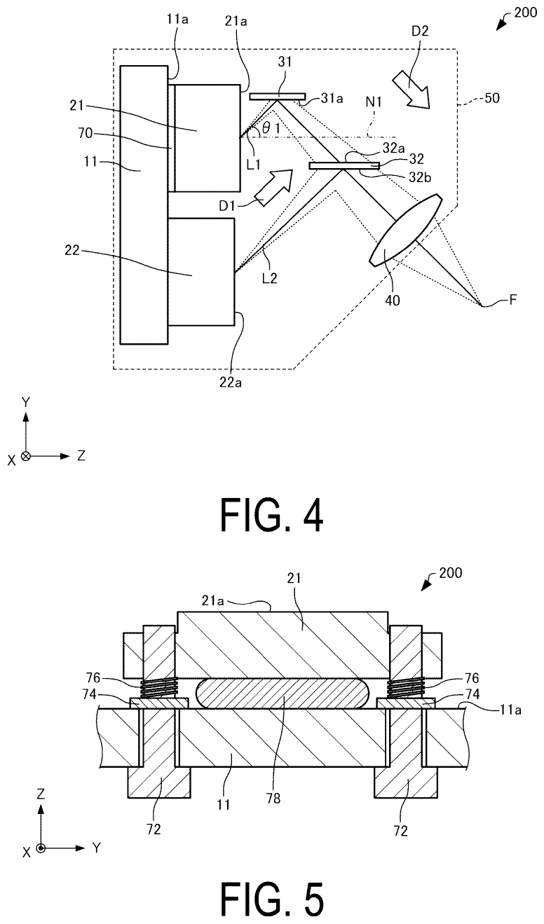

Next, a laser module according to a first modification of the embodiment will be described with reference to the drawings. FIG. 4 is a diagram schematically illustrating a laser module 200 according to the first modification of the embodiment.

In the following description, in the laser module 200 according to the first modification of the embodiment, the components with the same functions as those of the above-described laser module 100 according to the embodiment are denoted with the same reference numerals, and the description thereof is omitted.

In the laser module 100 described above, the second mirror 32 is a polarization beam combiner.

In contrast, in the laser module 200, the second mirror 32 is a dichroic mirror.

In the laser module 200, the first beam L1 emitted from the first semiconductor laser light source 21 and the second beam L2 emitted from the second semiconductor laser light source 22 have wavelengths different from each other. Thus, the second mirror 32, which is a dichroic mirror, can transmit the first beam L1 and reflect the second beam L2. For example, the semiconductor laser light sources 21 and 22, which are PCSELS, can adjust the wavelengths of the beams L1 and L2 by complex modulation. By using a PCSEL, a wavelength of emitted light can be finely set. The second mirror 32 transmits light having a predetermined wavelength or less and reflects light having a wavelength longer than the predetermined wavelength, for example.

In the laser module 200, as illustrated in FIG. 4, positions of the emission surfaces of the semiconductor laser light sources 21 and 22 in a direction along the first perpendicular line N1 are different from each other. Thus, even when the wavelengths of the beams L1 and L2 are different, light condensing positions and light condensing angles can be made uniform at the light condensing point F. In the illustrated example, the emission surface 21a of the first semiconductor laser light source 21 is located farther on the +Z-axis direction side than the emission surface 22a of the second semiconductor laser light source 22.

The laser module 200 includes a position adjustment mechanism 70 for adjusting a position of the first semiconductor laser light source 21 in the Z-axis direction. The position adjustment mechanism 70 can correct color aberration of the light condensing optical system 40.

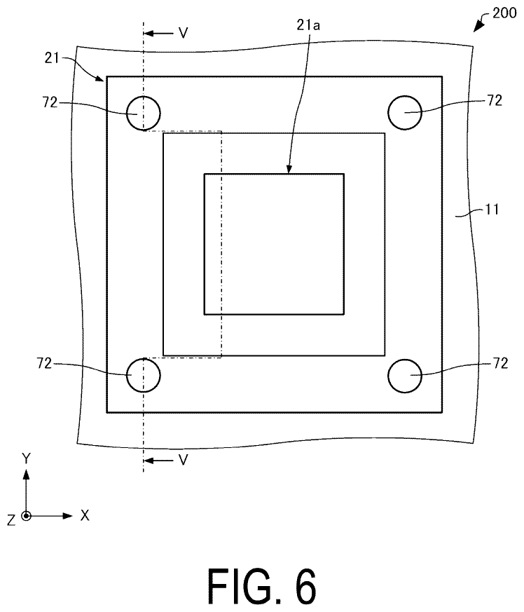

Here, FIG. 5 is a cross-sectional view schematically illustrating the first semiconductor laser light source 21 and the position adjustment mechanism 70 of the laser module 200 according to the first modification of the embodiment. FIG. 6 is a diagram schematically illustrating the first semiconductor laser light source 21 and the position adjustment mechanism 70 of the laser module 200 according to the first modification of the embodiment, as viewed from the Z-axis direction. Note that FIG. 5 is a cross-sectional view taken along line V-V in FIG. 6. Further, for the sake of convenience, FIG. 4 illustrates the position adjustment mechanism 70 in a simplified manner.

As illustrated in FIGS. 5 and 6, the first semiconductor laser light source 21 is provided at the first substrate 11 via the position adjustment mechanism 70. The position adjustment mechanism 70 includes, for example, an adjustment screw 72, a washer 74, and a spring 76.

The adjustment screw 72 penetrates the first substrate 11 and the first semiconductor laser light source 21. In the example illustrated in FIG. 6, the adjustment screws 72 are provided at four corners of the first semiconductor laser light source 21 as viewed from the Z-axis direction. In the example illustrated in FIG. 5, a head of the adjustment screw 72 is provided at the first substrate 11 on an opposite side to the first semiconductor laser light source 21. The adjustment screw 72 is rotatable about an axis parallel to the Z-axis as a rotation axis.

The washer 74 and the spring 76 are provided at the adjustment screw 72. The first semiconductor laser light source 21 is biased in a direction away from the first substrate 11 by the washer 74 and the spring 76. Accordingly, the first semiconductor laser light source 21 can be displaced in the Z-axis direction with respect to the first substrate 11 by rotating the adjustment screw 72.

A heat conductive paste 78 is provided between the first semiconductor laser light source 21 and the first substrate 11. The heat conductive paste 78 is in contact with the first semiconductor laser light source 21 and the first substrate 11. The heat conductive paste 78 has fluidity and shrinkability. Therefore, even when a distance between the first semiconductor laser light source 21 and the first substrate 11 changes, the heat conductive paste 78 can be in contact with the first semiconductor laser light source 21 and the first substrate 11. This allows heat generated in the first semiconductor laser light source 21 to be efficiently transferred to the first substrate 11.

As a method of correcting the color aberration of the light condensing optical system 40, for example, a method can be cited in which a power meter is provided at an imaging point of the condensing optical system 40, the adjustment screw 72 is rotated while the first semiconductor laser light source 21 is driven to displace the position of the first semiconductor laser light source 21 in the Z-axis direction, and adjustment is performed so that a value of the power meter becomes maximum.

In the laser module 200, the first beam L1 and the second beam L2 have the wavelengths different from each other, and the second mirror 32 is a dichroic mirror. Therefore, in the laser module 200, the first beam L1 and the second beam L2 can be multiplexed at the second mirror 32.

In the laser module 200, the positions of the emission surfaces in the direction along the first perpendicular line N1 are different from each other in the first semiconductor laser light source 21 and the second semiconductor laser light source 22. Therefore, in the laser module 200, the color aberration of the light condensing optical system 40 can be corrected.

Note that although not illustrated, the emission surface 21a of the first semiconductor laser light source 21 may be located farther on a-Z-axis direction side of the emission surface 22a than the second semiconductor laser light source 22. Further, the laser module 200 may include the position adjustment mechanism 70 for adjusting a position of the second semiconductor laser light source 22 in the Z-axis direction.

Further, the position adjustment mechanism 70 need not be provided, and an achromatic lens with corrected color aberration may be used as the light condensing optical system 40 to make the light condensing positions and the light condensing angles of the beams L1 and L2 uniform at the light condensing point F. This makes it possible to equalize an optical path length from the first semiconductor laser light source 21 to the second mirror 32 and an optical path length from the first semiconductor laser light source 21 to the second mirror 32.

### 2.2. Second Modification

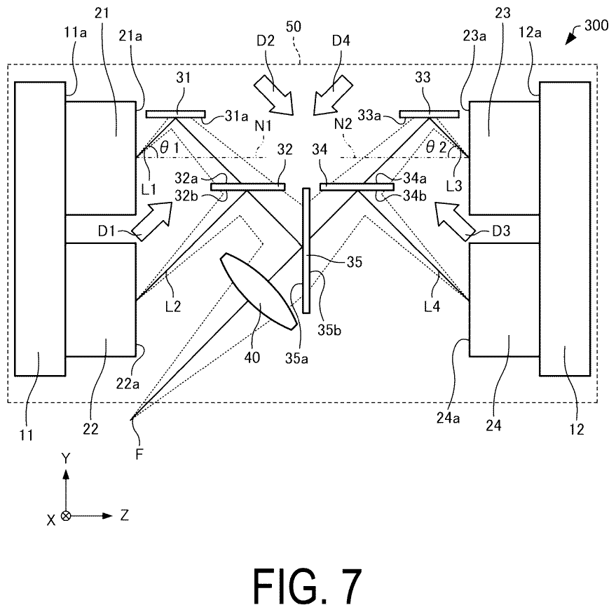

Next, a laser module according to a second modification of the embodiment will be described with reference to the drawings. FIG. 7 is a diagram schematically illustrating a laser module 300 according to the second modification of the embodiment.

In the following description, in the laser module 300 according to the second modification of the embodiment, the components with the same functions as those of the above-described laser module 100 according to the embodiment are denoted with the same reference numerals, and the description thereof is omitted.

As illustrated in FIG. 7, the laser module 300 is different from the laser module 100 described above in that a second substrate 12, a third semiconductor laser light source 23, a fourth semiconductor laser light source 24, a third mirror 33, a fourth mirror 34, and a fifth mirror 35 are included. The second substrate 12, the semiconductor laser light sources 23, 24, and the mirrors 33, 34, and 35 are accommodated in the housing 50.

The second substrate 12 is provided facing the first substrate 11. The second substrate 12 supports the third semiconductor laser light source 23 and the fourth semiconductor laser light source 24. The second substrate 12 includes a second plane 12a. The second plane 12a of the second substrate 12 faces the first plane 11a of the first substrate 11. The second plane 12a is a flat surface. A material of the second substrate 12 is the same as a material of the first substrate 11, for example. The second substrate 12 dissipates heat generated in the semiconductor laser light sources 23 and 24.

The third semiconductor laser light source 23 is provided at the second plane 12a of the second substrate 12. The third semiconductor laser light source 23 is directly provided at the second plane 12a, for example. The third semiconductor laser light source 23 is provided facing the first semiconductor laser light source 21. The third semiconductor laser light source 23 includes an emission surface 23a that emits light. The emission surface 21a and the emission surface 23a are parallel to each other. A second perpendicular line N2 of the emission surface 23a is parallel to the Z-axis. The emission surface 23a is a surface of the third semiconductor laser light source 23 on an opposite side to the second substrate 12.

The third semiconductor laser light source 23 emits a third beam L3. In particular, the third semiconductor laser light source 23 emits the third beam L3 in a third direction D3 inclined at a second angle θ2 with respect to the second perpendicular line N2. The second angle θ2 is an angle larger than 0° and smaller than 90°, for example, from 15° to 75°, and may be from 30° to 60°. In the illustrated example, the second angle θ2 is 45°. The first angle θ1 and the second angle θ2 are equal to each other.

The fourth semiconductor laser light source 24 is provided at the second plane 12a of the second substrate 12. The fourth semiconductor laser light source 24 is directly provided at the second plane 12a, for example. The fourth semiconductor laser light source 24 is provided facing the second semiconductor laser light source 22. In the illustrated example, the semiconductor laser light sources 23 and 24 are arranged in the Y-axis direction. The emission surface 23a of the third semiconductor laser light source 23 and an emission surface 24a of the fourth semiconductor laser light source 24 are located at the same plane. The fourth semiconductor laser light source 24 is provided facing the second semiconductor laser light source 22.

The fourth semiconductor laser light source 24 emits a fourth beam L4. In particular, the fourth semiconductor laser light source 24 emits the fourth beam L4 in the third direction D3 inclined at the second angle θ2 with respect to the second perpendicular line N2. An optical axis of the first beam L1, an optical axis of the second beam L2, an optical axis of the third beam L3, and an optical axis of the fourth beam L4 are parallel to each other. A radiation angle of the first beam L1, a radiation angle of the second beam L2, a radiation angle of the third beam L3, and a radiation angle of the fourth beam L4 are, for example, the same as each other. The semiconductor laser light sources 23 and 24 are, for example, photonic crystal surface emitting lasers.

The third mirror 33 is provided parallel to the second perpendicular line N2. To be specific, the third mirror 33 includes a reflecting surface 33a parallel to the second perpendicular line N2. A perpendicular line of the reflecting surface 33a is orthogonal to the second perpendicular line N2 of the emission surface 23a. The third mirror 33 has, for example, a plate shape. The third mirror 33 reflects the third beam L3 emitted in the third direction D3 from the third semiconductor laser light source 23 at the reflecting surface 33a. In the illustrated example, the mirrors 31 and 33 are arranged in the Z-axis direction.

The fourth mirror 34 is provided parallel to the second perpendicular line N2. To be specific, the fourth mirror 34 includes a transmitting surface 34a and a reflecting surface 34b parallel to second perpendicular line N2. A perpendicular line of the transmitting surface 34a and a perpendicular line of the reflecting surface 34b are orthogonal to the second perpendicular line N2. The transmitting surface 34a and the reflecting surface 34b are surfaces facing away from each other. In the illustrated example, the fourth mirror 34 is located farther in the −Z-axis direction than the third mirror 33. An optical path length from the third semiconductor laser light source 23 to the fourth mirror 34 and an optical path length from the fourth semiconductor laser light source 24 to the fourth mirror 34 are, for example, the same. In the illustrated example, the mirrors 32 and 34 are arranged in the Z-axis direction.

The fourth mirror 34 is, for example, a polarization beam combiner. For example, the semiconductor laser light sources 23 and 24, which are PCSELs, can adjust polarization directions of the beams L3 and L4 by complex modulation. The polarization directions of the beams L3 and L4 are different from each other. For example, the third beam L3 is P-polarized light, and the fourth beam L4 is S-polarized light.

The fourth mirror 34 transmits the third beam L3 reflected by the third mirror 33 in a fourth direction D4, and reflects the fourth beam L4 emitted in the third direction D3 from the fourth semiconductor laser light source 24 in the fourth direction D4. Then, the fourth mirror 34 multiplexes the third beam L3 and the fourth beam L4 and guides the multiplexed beams to the fifth mirror 35. The third beam L3 reflected by the third mirror 33 enters the third mirror 33 from the transmitting surface 34a and is emitted from the reflecting surface 34b. The fourth beam L4 emitted from the fourth semiconductor laser light source 24 is reflected by the reflecting surface 34b.

The fifth mirror 35 is provided between the first substrate 11 and the second substrate 12. The fifth mirror 35 is provided in an optical path from the second mirror 32 to the light condensing optical system 40. Further, the fifth mirror 35 is provided in an optical path from the fourth mirror 34 to the light condensing optical system 40. The fifth mirror 35 is orthogonal to the first perpendicular line N1 of the emission surface 21a. To be more specific, the fifth mirror 35 includes a reflecting surface 35a and a transmitting surface 35b that are orthogonal to the first perpendicular line N1. A perpendicular line of the reflecting surface 35a and a perpendicular line of the transmitting surface 35b are parallel to the first perpendicular line N1. The reflecting surface 35a and the transmitting surface 35b are surfaces facing away from each other.

The fifth mirror 35 is a dichroic mirror. The first beam L1 and the second beam L2 are light having a first wavelength. The third beam L3 and the fourth beam L4 are light having a second wavelength different from the first wavelength. Therefore, the fifth mirror 35, which is a dichroic mirror, can reflect the beams L1 and L2 and transmit the beams L3 and L4. To be specific, the fifth mirror 35 reflects the beams L1 and L2 from the second mirror 32 in the fourth direction D4, and transmits the beams L3 and L4 from the fourth mirror 34 in the fourth direction D4. The beams L1 and L2 from the second mirror 32 are reflected by the reflecting surface 35a. The beams L3 and L4 from the fourth mirror 34 enter the fifth mirror 35 from the transmitting surface 35b, and are emitted from the reflecting surface 35a. The fifth mirror 35 multiplexes the beams L1 and L2 and the beams L3 and L4.

Note that an optical path length from the first semiconductor laser light source 21 to the fifth mirror 35, an optical path length from the second semiconductor laser light source 22 to the fifth mirror 35, an optical path length from the third semiconductor laser light source 23 to the fifth mirror 35, and an optical path length from the fourth semiconductor laser light source 24 to the fifth mirror 35 may be the same as each other.

Alternatively, the optical path length from the first semiconductor laser light source 21 to the fifth mirror 35 and the optical path length from the second semiconductor laser light source 22 to the fifth mirror 35 may be the same as each other, the optical path length from the third semiconductor laser light source 23 to the fifth mirror 35 and the optical path length from the fourth semiconductor laser light source 24 to the fifth mirror 35 may be the same as each other, and the optical path length from the first semiconductor laser light source 21 to the fifth mirror 35 and the optical path length from the third semiconductor laser light source 23 to the fifth mirror 35 may be different from each other.

The light condensing optical system 40 condenses the first beam L1, the second beam L2, the third beam L3, and the fourth beam L4. To be specific, the light condensing optical system 40 condenses the beams L1, L2, L3, and L4 from the fifth mirror 35 at the light condensing point F.

The laser module 300 includes the second substrate 12 provided facing the first substrate 11, the third semiconductor laser light source 23 provided at the second substrate 12 and configured to emit the third bean L3 in the third direction D3 inclined at the second angle θ2 larger than 0° and smaller than 90° with respect to the second perpendicular line N2 of the emission surface 23a, the fourth semiconductor laser light source 24 provided at the second substrate 12 and configured to emit the fourth beam L4 in the third direction D3, the third mirror 33 provided parallel to the second perpendicular line N2 and configured to reflect the third beam L3 emitted in the third direction D3 from the third semiconductor laser light source 23, the fourth mirror 34 configured to transmit the third beam L3 reflected by the third mirror 33 in the fourth direction D4 and reflect the fourth beam L4 emitted from the fourth semiconductor laser light source 24 in the fourth direction D4, and the fifth mirror 35 provided in the optical path from the second mirror 32 to the light condensing optical system 40 and configured to reflect the first beam L1 and the second beam L2 from the second mirror 32 and transmit the third beam L3 and the fourth beam L4 from the fourth mirror 34. The emission surface 21a of the first semiconductor laser light source 21 and the emission surface 23a of the third semiconductor laser source 23 are parallel to each other. The light condensing optical system 40 condenses the first beam L1, the second beam L2, the third beam L3, and the fourth beam L4 from the fifth mirror 35.

Therefore, in the laser module 300, the first beam L1, the second beam L2, the third beam L3, and the fourth beam L4 can be multiplexed. Thus, a high output can be achieved.

In the laser module 300, the first beam L1 and the second beam L2 are the light having the first wavelength, the third beam L3 and the fourth beam L4 are the light having the second wavelength different from the first wavelength, and the fifth mirror 35 is a dichroic mirror. Therefore, in the laser module 300, the first beam L1, the second beam L2, the third beam L3, and the fourth beam L4 can be multiplexed at the fifth mirror 35.

In the laser module 300, the third semiconductor laser light source 23 and the fourth semiconductor laser light source 24 are provided at the second plane 12a of the second substrate 12. Therefore, in the laser module 300, temperature characteristics of the semiconductor laser light sources 23 and 24 can be made more uniform. Therefore, temperature control for the semiconductor laser light sources 23 and 24 can be easily performed.

Note that, although the case where the second mirror 32 and the fourth mirror 34 are polarization beam combiners and the fifth mirror 35 is a dichroic mirror has been described above, the second mirror 32 and the fourth mirror 34 may be dichroic mirrors and the fifth mirror 35 may be a polarization beam combiner.

In this case, the first beam L1 and the third beam L3 are light having a first wavelength, and the second beam L2 and the fourth beam L4 are light having a second wavelength different from the first wavelength. The beams L1 and L2 enter the fifth mirror 35 as first polarized beams, and the beams L3 and L4 enter the fifth mirror 35 as second polarized beams different from the first polarized beam. The first polarized beam may be S-polarized light, and the second polarized beam may be P-polarized light. Although not illustrated, the semiconductor laser light sources 21 and 23 may be provided at the substrates 11 and 12 via the position adjustment mechanisms 70, respectively. The semiconductor laser light sources 21, 22, 23, and 24 may emit light having wavelengths different from each other.

However, semiconductor laser light sources that emit light having the same wavelength have the same temperature characteristics. Therefore, it is easier to control temperature when the semiconductor laser light sources 21 and 22 provided at the first substrate 11 emit light having the same wavelength and the semiconductor laser light sources 23 and 24 provided at the second substrate 12 emit light having the same wavelength. Thus, stabilization with respect to an environment can be achieved.

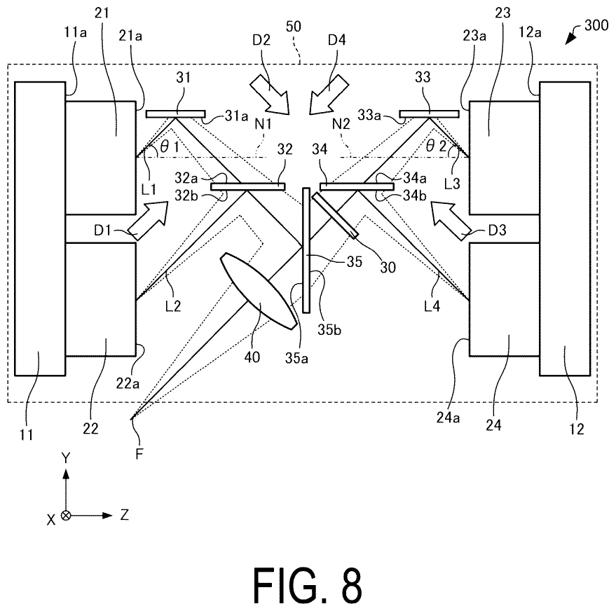

In addition, when the second mirror 32 and the fourth mirror 34 are dichroic mirrors and the fifth mirror 35 is a polarization beam combiner, the semiconductor laser light sources 21, 22, 23, and 24 may emit the first polarized beams, and the λ/2 plate 30 may be provided in an optical path from the fourth mirror 34 to the fifth mirror 35, as illustrated in FIG. 8. Accordingly, the beams L3 and L4 emitted from the semiconductor laser light sources 23 and 24 can be converted from the first polarized beams into the second polarized beams. By disposing the fifth mirror 35, which is a polarization beam combiner, downstream of the mirrors 32 and 34, which are dichroic mirrors, the number of polarization beam combiners can be reduced, and cost reduction can be achieved.

### 2.3. Third Modification

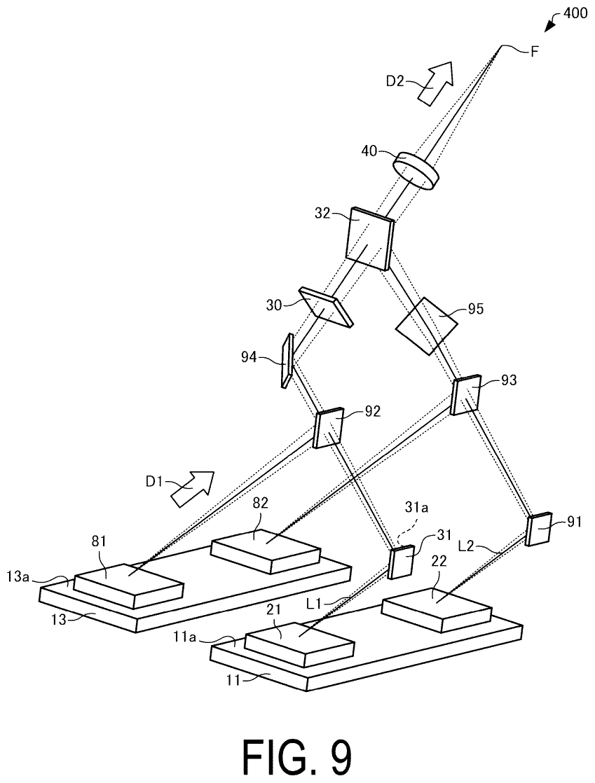

Next, a laser module according to a third modification of the embodiment will be described with reference to the drawings. FIG. 9 is a perspective view schematically illustrating a laser module 400 according to the third modification of the embodiment.

In the following description, in the laser module 400 according to the third modification of the embodiment, the components with the same functions as those of the above-described laser module 100 according to the embodiment are denoted with the same reference numerals, and the description thereof is omitted.

As illustrated in FIG. 9, the laser module 400 is different from the laser module 100 described above in that a substrate 13, a semiconductor laser light source 81, 82, and mirrors 91, 93, 94, and 95 are included.

The substrate 13 is separated from the first substrate 11. A material of the substrate 13 is the same as a material of the first substrate 11, for example. The substrate 13 includes a plane 13a. A perpendicular line of the plane 13a is parallel to, for example, a perpendicular line of the first plane 11a of the first substrate 11.

The semiconductor laser light sources 81 and 82 are provided at the plane 13a of the substrate 13. The semiconductor laser light sources 81 and 82 emit light in the first direction D1. An optical axis of the beam L1 emitted from the first semiconductor laser light source 21, an optical axis of the beam L2 emitted from the second semiconductor laser light source 22, an optical axis of a beam emitted from the third semiconductor laser light source 23, and an optical axis of a beam emitted from the fourth semiconductor laser light source 24 are parallel to each other.

The semiconductor laser light sources 81 and 82 emit light having wavelengths the same as each other. The semiconductor laser light sources 21 and 22 emit light having wavelengths the same as each other. The semiconductor laser light sources 21 and 81 emit light having wavelengths different from each other. The semiconductor laser light sources 21, 22, 81, and 82 each emit light having the same polarization. The semiconductor laser light sources 21, 22, 81, and 82 emit, for example, S-polarized light. The semiconductor laser light sources 81 and 82 have basically the same configuration as that of the semiconductor laser light source 21 and 22 except for the wavelengths of the emitted light.

The mirror 91 reflects the second beam L2 emitted from the second semiconductor laser light source 22 in the first direction D1. A direction of the second beam L2 reflected by the mirror 91 is the same as a direction of the first beam L1 reflected by the first mirror 31. A reflecting surface of the mirror 91 and the reflecting surface 31a of the first mirror 31 are located at the same plane.

A mirror 92 transmits the first beam L1 reflected by the first mirror 31 and reflects light emitted in the first direction D1 from the semiconductor laser light source 81. The mirror 93 transmits the second beam 12 reflected by the mirror 91 and reflects light emitted in the first direction D1 from the semiconductor laser light source 82. The mirrors 92 and 93 are dichroic mirrors. A reflecting surface of the mirror 92 and a reflecting surface of the mirror 93 are located at the same plane.

The mirror 94 reflects light from the mirror 92. The light reflected by the mirror 94 is transmitted through the λ/2 plate 30. Accordingly, the light reflected by the mirror 94 is converted from S-polarized light into P-polarized light, for example. The mirror 95 reflects light from the mirror 93.

The second mirror 32 transmits light reflected by the mirror 94 and transmitted through λ/2 in the second direction D2, and reflects light reflected by the mirror 95 in the second direction D2. The second mirror 32 is a polarization beam combiner.

The light condensing optical system 40 condenses the first beam L1 emitted from the first semiconductor laser light source 21, the second beam L2 emitted from the second semiconductor laser light source 22, a beam emitted from the semiconductor laser light source 81, and a beam emitted from the semiconductor laser light source 82. Therefore, in the laser module 400, it is possible to achieve a higher output as compared to the laser module 100, for example.

### 2.4. Fourth Modification

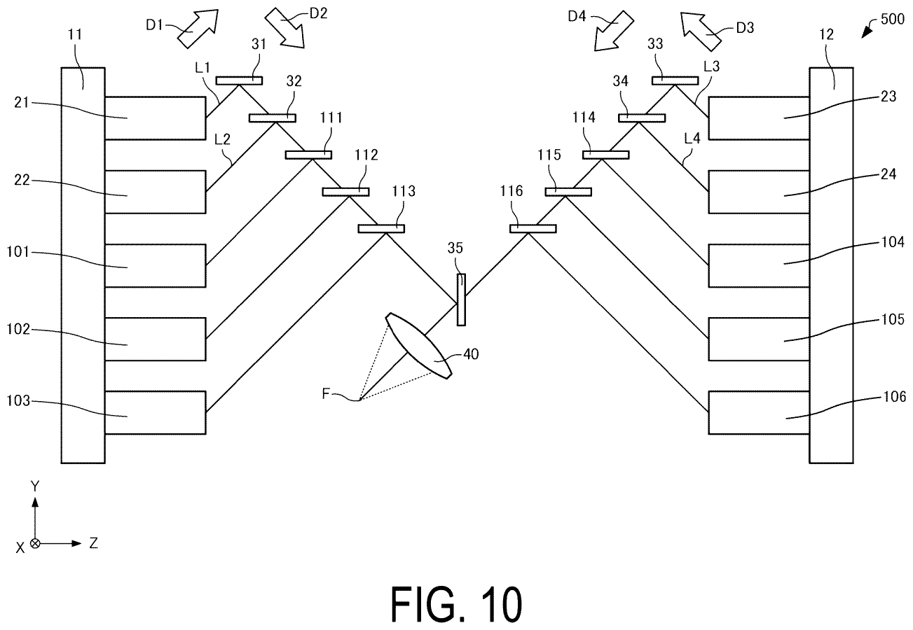

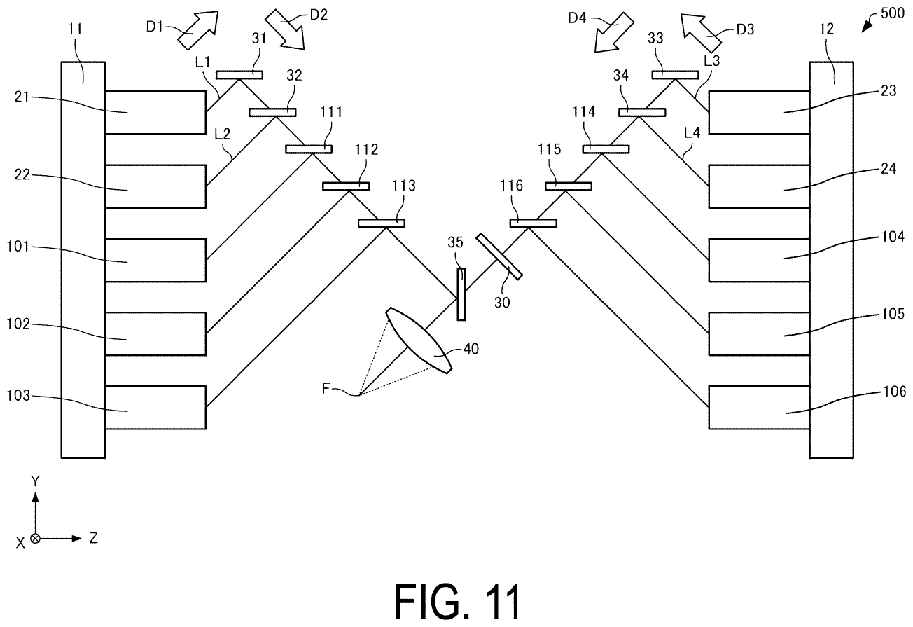

Next, a laser module according to a fourth modification of the embodiment will be described with reference to the drawings. FIG. 10 is a diagram schematically illustrating a laser module 500 according to the fourth modification of the embodiment.

In the following description, in the laser module 500 according to the fourth modification of the embodiment, the components with the same functions as those of the above-described laser module 300 according to the second modification of the embodiment are denoted with the same reference numerals, and the description thereof is omitted.

As illustrated in FIG. 10, the laser module 500 is different from the laser module 300 described above in that semiconductor laser light sources 101, 102, 103, 104, 105, 106 and mirrors 111, 112, 113, 114, 115, and 116 are included.

Note that for convenience, in FIG. 10, only an optical axis is illustrated in an optical path from a semiconductor laser light source to a light condensing optical system, and spread of light is omitted. The same applies to FIGS. 11 to 15 described later.

The semiconductor laser light sources 101, 102, and 103 are provided at the first substrate 11. In the illustrated example, the semiconductor laser light sources 21, 22, 101, 102, and 103 are arrayed in this order in the Y-axis direction. The semiconductor laser light sources 101, 102, and 103 emit light in the first direction D1. An optical axis of the beam L1 emitted from the first semiconductor laser light source 21, an optical axis of the beam L2 emitted from the second semiconductor laser light source 22, an optical axis of a beam emitted from the semiconductor laser light source 101, an optical axis of a beam emitted from the semiconductor laser light source 102, and an optical axis of a beam emitted from the semiconductor laser light source 103 are parallel to each other.

The semiconductor laser light sources 21, 22, 101, 102, and 103 emit light having wavelengths different from each other. Although not illustrated, each of the semiconductor laser light sources 21, 22, 101, 102, and 103 may be provided at the first substrate 11 via the position adjustment mechanism 70. The semiconductor laser light sources 21, 22, 101, 102, and 103 each emit light having the same polarization. The semiconductor laser light sources 21, 22, 101, 102, and 103 emit, for example, S-polarized light. The semiconductor laser light sources 101, 102, and 103 have basically the same configuration as that of the semiconductor laser light sources 21 and 22 except for the wavelengths of the emitted light.

The semiconductor laser light sources 104, 105, and 106 are provided at the second substrate 12. In the illustrated example, the semiconductor laser light sources 23, 24, 104, 105, and 106 are arrayed in this order in the Y-axis direction. The semiconductor laser light sources 104, 105, and 106 emit light in the third direction D3. An optical axis of the beam L3 emitted from the third semiconductor laser light source 23, an optical axis of the beam L4 emitted from the fourth semiconductor laser light source 24, an optical axis of a beam emitted from the semiconductor laser light source 104, an optical axis of a beam emitted from the semiconductor laser light source 105, and an optical axis of a beam emitted from the semiconductor laser light source 106 are parallel to each other.

The semiconductor laser light sources 23, 24, 104, 105, and 106 emit light having wavelengths different from each other. Although not illustrated, each of the semiconductor laser light sources 23, 24, 104, 105, and 106 may be provided at the second substrate 12 via the position adjustment mechanism 70. The semiconductor laser light sources 23, 24, 104, 105, and 106 each emit light having the same polarization. The semiconductor laser light sources 23, 24, 104, 105, and 106 emit P-polarized light, for example. The semiconductor laser light sources 104, 105, and 106 have basically the same configuration as that of the semiconductor laser light sources 23 and 24 except for the wavelengths of the emitted light.

The mirror 111 transmits light from the second mirror 32 in the second direction D2, and reflects light emitted in the first direction D1 from the semiconductor laser light source 101 in the second direction D2. The mirror 112 transmits light from the mirror 111 in the second direction D2, and reflects light emitted in the first direction D1 from the semiconductor laser light source 102 in the second direction D2. The mirror 113 transmits light from the mirror 112 in the second direction D2, and reflects light emitted in the first direction D1 from the semiconductor laser light source 103 in the second direction D2. The mirrors 32, 111, 112, and 113 are dichroic mirrors.

The mirror 114 transmits light from the fourth mirror 34 in the fourth direction D4, and reflects light emitted in the third direction D3 from the semiconductor laser light source 104 in the fourth direction D4. The mirror 115 transmits light from the mirror 114 in the fourth direction D4, and reflects light emitted in the third direction D3 from the semiconductor laser light source 105 in the fourth direction D4. The mirror 116 transmits light from the mirror 115 in the fourth direction D4, and reflects light emitted in the third direction D3 from the semiconductor laser light source 106 in the fourth direction D4. The mirrors 114, 115, and 116 are dichroic mirrors.

The fifth mirror 35 reflects light from the mirror 113 in the fourth direction D4 and transmits light from the mirror 116 in the fourth direction D4.

The light condensing optical system 40 condenses beams emitted from the semiconductor laser light source 21, 22, 23, 24, 101, 102, 103, 104, 105, and 106. Therefore, in the laser module 500, it is possible to achieve a higher output as compared to, for example, the laser module 300.

The semiconductor laser light sources 23, 24, 104, 105, and 106 may emit light having the same polarization as that of the semiconductor laser light sources 21, 22, 101, 102, and 103, for example. In this case, as illustrated in FIG. 11, the λ/2 plate 30 is provided in an optical path from the mirror 116 to the fifth mirror 35. Accordingly, light emitted from the semiconductor laser light sources 23, 24, 104, 105, and 106 can be converted from S-polarized light into P-polarized light, for example.

Further, the number of semiconductor laser light sources and the number of mirrors are not particularly limited.

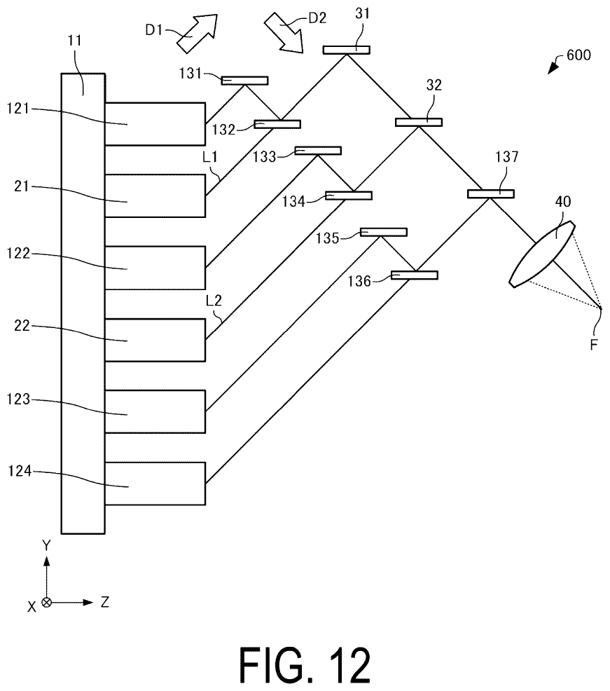

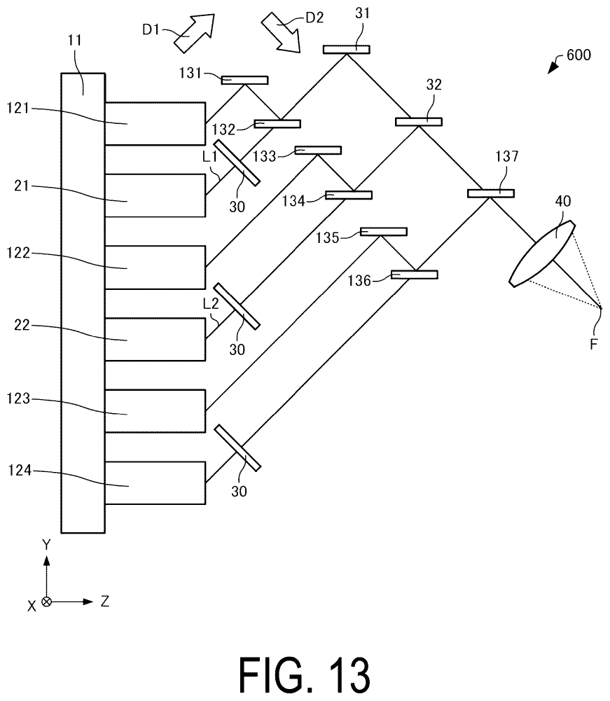

2.5. Fifth Modification Next, a laser module according to a fifth modification of the embodiment will be described with reference to the drawings. FIG. 12 is a diagram schematically illustrating a laser module 600 according to the fifth modification of the embodiment.

In the following description, in the laser module 600 according to the fifth modification of the embodiment, the components with the same functions as those of the above-described laser module 100 according to the embodiment are denoted with the same reference numerals, and the description thereof is omitted.

As illustrated in FIG. 12, the laser module 600 is different from the laser module 100 described above in that semiconductor laser light sources 121, 122, 123, 124 and mirrors 131, 132, 133, 134, 135, 136, and 137 are included.

The semiconductor laser light sources 121, 122, 123, and 124 are provided at the first substrate 11. In the illustrated example, the semiconductor laser light sources 121, 21, 122, 22, 123, and 124 are arrayed in this order in the Y-axis direction. The semiconductor laser light sources 121, 122, 123, and 124 emit light in the first direction D1. An optical axis of the beam L1 emitted from the first semiconductor laser light source 21, an optical axis of the beam L2 emitted from the second semiconductor laser light source 22, an optical axis of a beam emitted from the semiconductor laser light source 121, an optical axis of a beam emitted from the semiconductor laser light source 122, an optical axis of a beam emitted from the semiconductor laser light source 123, and an optical axis of a beam emitted from the semiconductor laser light source 124 are parallel to each other.

The semiconductor laser light sources 21 and 121 emit light having wavelengths the same as each other. The semiconductor laser light sources 22 and 122 emit light having wavelengths the same as each other. The semiconductor laser light sources 123 and 124 emit light having wavelengths the same as each other. The semiconductor laser light sources 21, 22, and 123 emit light having the wavelengths different from each other. Although not illustrated, each of the semiconductor laser light sources 21, 22, 121, 122, 123, and 124 may be provided at the first substrate 11 via the position adjustment mechanism 70.

The semiconductor laser light source 21, 22, and 124 emit, for example, first polarized beams. The semiconductor laser light source 21, 22, and 124 emit, for example, P-polarized light. The semiconductor laser light sources 121, 122, and 123 emit second polarized beams different from the first polarized beams. The semiconductor laser light source 121, 122, and 123 emit, for example, S-polarized light.

The semiconductor laser light sources 121, 122, and 123 have basically the same configuration as that of the semiconductor laser light sources 21 and 22 except for the wavelengths and the polarization of the emitted light. The semiconductor laser light source 124 has basically the same configuration as that of the semiconductor laser light source 21 and 22 except for the wavelengths of the emitted light.

The mirror 131 reflects light emitted in the first direction D1 from the semiconductor laser light source 121 in the second direction D2.

The mirror 132 transmits light emitted in the first direction D1 from the first semiconductor laser light source 21 in the first direction D1, and reflects light reflected by the mirror 131 in the first direction D1. The mirror 132 is a polarization beam combiner.

The mirror 133 reflects light emitted in the first direction D1 from the semiconductor laser light source 122 in the second direction D2.

The mirror 134 transmits light emitted in the first direction D1 from the second semiconductor laser light source 22 in the first direction D1, and reflects light reflected by the mirror 133 in the first direction D1. The mirror 134 is a polarization beam combiner.

The mirror 135 reflects light emitted in the first direction D1 from the semiconductor laser light source 123 in the second direction D2.

The mirror 136 transmits light emitted in the first direction D1 from the semiconductor laser light source 124 in the first direction D1, and reflects light reflected by the mirror 135 in the first direction D1. The mirror 136 is a polarization beam combiner.

The first mirror 31 reflects light from the mirror 132 in the second direction D2.

The second mirror 32 transmits light from the first mirror 31 in the second direction D2 and reflects light from the mirror 134 in the second direction D2. The second mirror 32 is a dichroic mirror.

The mirror 137 transmits light from the second mirror 32 in the second direction D2 and reflects light from the mirror 136 in the second direction D2. The mirror 137 is a dichroic mirror.

The light condensing optical system 40 condenses beams emitted from the semiconductor laser light sources 21, 22, 121, 122, 123, and 124. Therefore, in the laser module 600, it is possible to achieve a higher output as compared to, for example, the laser module 100.

Note that the semiconductor laser light sources 21, 22, 121, 122, 123, and 124 may each emit light having the same polarization. In this case, as illustrated in FIG. 13, the λ/2 plate 30 is provided in each of an optical path from the first semiconductor laser light source 21 to the mirror 132, an optical path from the second semiconductor laser light source 22 to the mirror 134, and an optical path from the semiconductor laser light source 124 to the mirror 136. Accordingly, light emitted from the semiconductor laser light sources 21, 22, and 124 can be converted from S-polarized light into P-polarized light, for example.

Further, the number of semiconductor laser light sources and the number of mirrors are not particularly limited.

### 2.6. Sixth Modification

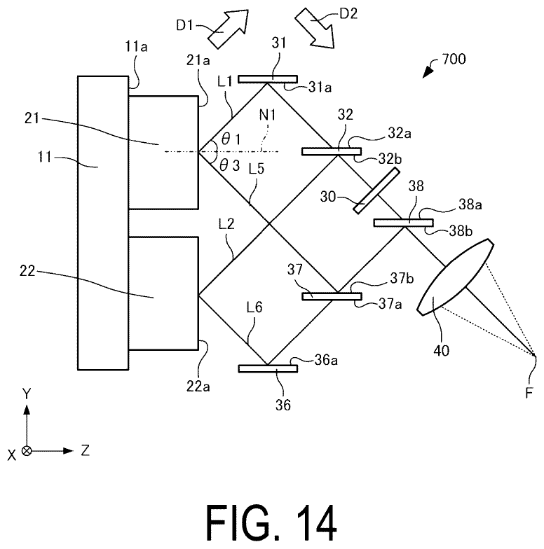

Next, a laser module according to a sixth modification of the embodiment will be described with reference to the drawings. FIG. 14 is a diagram schematically illustrating a laser module 700 according to the sixth modification of the embodiment.

In the following description, in the laser module 700 according to the sixth modification of the embodiment, the components with the same functions as those of the above-described laser module 100 according to the embodiment are denoted with the same reference numerals, and the description thereof is omitted.

The laser module 700 is different from the laser module 100 described above in that the first semiconductor laser light source 21 emits the first beam L1 and a fifth beam L5, and the second semiconductor laser light source 22 emits the second beam L2 and a sixth beam L6, as illustrated in FIG. 14.

The first semiconductor laser light source 21 emits the fifth beam L5 in a fifth direction D5 inclined at a third angle θ3 symmetrical to the first angle θ1 with respect to the first perpendicular line N1. The first angle θ1 and the third angle θ3 are the same in magnitude. The first semiconductor laser light source 21, which is a PCSEL, can emit the first beam L1 and the fifth beam L5 by complex modulation.

The second semiconductor laser light source 22 emits the sixth beam L6 in the fifth direction D5. The second semiconductor laser light source 22, which is a PCSEL, can emit the second beam L2 and the sixth beam L6 by complex modulation. An optical axis of the fifth beam L5 emitted from the first semiconductor laser light source 21 and an optical axis of the sixth beam L6 emitted from the second semiconductor laser light source 22 are parallel to each other.

Polarization of the beams L1 and L5 emitted from the first semiconductor laser light source 21 and polarization of the beams L2 and L6 emitted from the second semiconductor laser light source 22 are the same as each other. The semiconductor laser light sources 21 and 22 emit, for example, S-polarized light. A radiation angle of the first beam L1, a radiation angle of the second beam L2, a radiation angle of the fifth beam L5, and a radiation angle of the sixth beam L6 are, for example, the same as each other.

Wavelengths of the beams L1 and L5 emitted from the first semiconductor laser light source 21 are the same as each other. Wavelengths of the beams L2 and L6 emitted from the second semiconductor laser light source 22 are the same as each other. The wavelength of the beam L1 emitted from the first semiconductor laser light source 21 and the wavelength of the beam L2 emitted from the second semiconductor laser light source 22 are different from each other. The second mirror 32 is a dichroic mirror. Although not illustrated, each of the semiconductor laser light sources 21 and 22 may be provided at the first substrate 11 via the position adjustment mechanism 70.

The laser module 700 includes a sixth mirror 36, a seventh mirror 37, and an eighth mirror 38.

The sixth mirror 36 is provided parallel to the first perpendicular line N1. To be specific, the sixth mirror 36 includes a reflecting surface 36a parallel to the first perpendicular line N1. A perpendicular line of the reflecting surface 36a is orthogonal to the first perpendicular line N1. The sixth mirror 36 has, for example, a plate shape. The sixth mirror 36 reflects the sixth beam L6 emitted from the second semiconductor laser light source 22 in the fifth direction D5 at the reflecting surface 36a. In the illustrated example, the first mirror 31 and the sixth mirror 36 are arranged in the Y-axis direction.

The seventh mirror 37 is provided parallel to the first perpendicular line N1. To be more specific, the seventh mirror 37 includes a transmitting surface 37a and a reflecting surface 37b parallel to the first perpendicular line N1. A perpendicular line of the transmitting surface 37a and a perpendicular line of the reflecting surface 37b are orthogonal to the first perpendicular line N1. The transmitting surface 37a and the reflecting surface 37b are surfaces facing away from each other. In the illustrated example, the second mirror 32 and the seventh mirror 37 are arranged in the Y-axis direction.

The seventh mirror 37 is a dichroic mirror. The seventh mirror 37 transmits the sixth beam L6 reflected by the sixth mirror 36 in a sixth direction D6, and reflects the fifth beam L5 emitted from the first semiconductor laser light source 21 in the sixth direction D6. The seventh mirror 37 multiplexes the fifth beam L5 and the sixth beam L6. The sixth beam L6 reflected by the sixth mirror 36 enters the seventh mirror 37 from the transmitting surface 37a, and is emitted from the reflecting surface 37b. The fifth beam L5 emitted from the first semiconductor laser light source 21 is reflected by the reflecting surface 37b.

The λ/2 plate 30 is provided between the eighth mirror 38 and the second mirror 32. The λ/2 plate converts the first beam L1 and the second beam L2 into P-polarized light.

The eighth 38 is provided in an optical path from the second mirror 32 to the light condensing optical system 40. Further, the eighth mirror 38 is provided in an optical path from the seventh mirror 37 to the light condensing optical system 40. The eighth mirror 38 is provided parallel to the first perpendicular line N1. To be more specific, the eighth mirror 38 includes a transmitting surface 38a and a reflecting surface 38b parallel to the first perpendicular line N1. The transmitting surface 38a and the reflecting surface 38b are surfaces facing away from each other.

The eighth mirror 38 transmits L1 and L2 from the second mirror 32 in the second direction D2, and reflects the beams L5 and L6 from the seventh mirror 37 in the second direction D2. The eighth mirror 38 multiplexes the beams L1 and L2, and the beams L5 and L6. The beams L1 and L2 from the second mirror 32 enter the eighth mirror 38 from the transmitting surface 38a and are emitted from the reflecting surface 38b. The beams L5 and L6 from the seventh mirror 37 are reflected by the reflecting surface 38b.

The light condensing optical system 40 condenses the first beam L1, the second beam L2, the fifth beam L5, and the sixth beam L6. Therefore, in the laser module 700, it is possible to achieve a higher output as compared to the laser module 100.

### 2.7. Seventh Modification

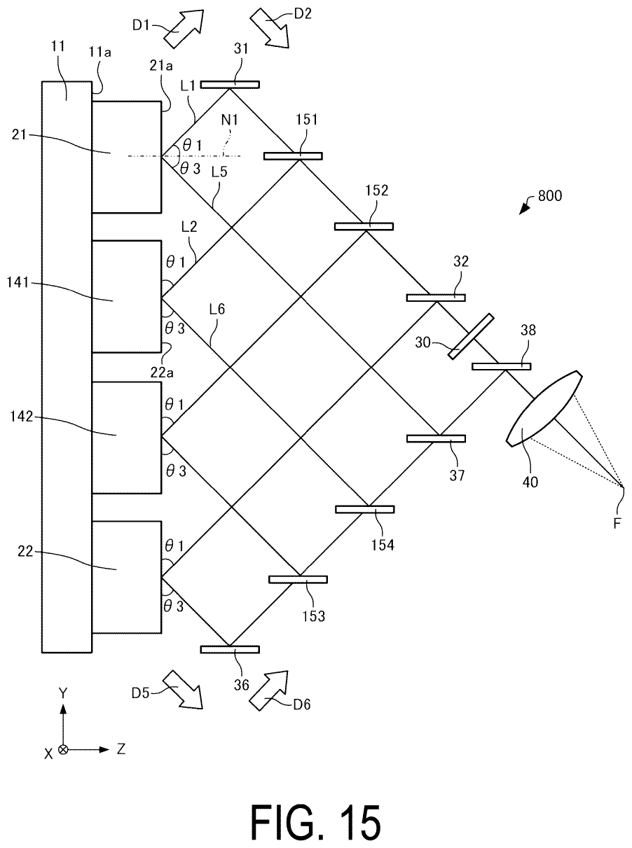

Next, a laser module according to a seventh modification of the embodiment will be described with reference to the drawings. FIG. 15 is a diagram schematically illustrating a laser module 800 according to the seventh modification of the embodiment.

In the following description, in the laser module 800 according to the seventh modification of the embodiment, the components with the same functions as those of the above-described laser module 700 according to the sixth modification of the embodiment are denoted with the same reference numerals, and the description thereof is omitted.

As illustrated in FIG. 15, the laser module 800 is different from the laser module 700 described above in that a semiconductor laser light sources 141, 142, and mirrors 151, 152, 153, and 154 are included.

The semiconductor laser light sources 141 and 142 are provided at the first substrate 11. In the illustrated example, the semiconductor laser light sources 21, 141, 142, and 22 are arrayed in this order in the Y-axis direction. The semiconductor laser light source 141 emits light in the first direction D1 and the fifth direction D5. The semiconductor laser light source 142 emits light in the first direction D1 and the fifth direction D5. The semiconductor laser light sources 141 and 142, which are PCSELs, can emit light in the first direction D1 and the fifth direction D5 by complex modulation.

Polarization of light emitted from each of the semiconductor laser light sources 21, 22, 141, and 142 is the same. Wavelengths of light emitted from the semiconductor laser light sources 21, 22, 141, and 142 are different from each other. Although not illustrated, each of the semiconductor laser light sources 21, 22, 141, 142 may be provided at the first substrate 11 via the position adjustment mechanism 70.

The mirror 151 transmits the first beam L1 reflected by the first mirror 31 in the second direction D2, and reflects light emitted in the first direction D1 from the semiconductor laser light source 141 in the second direction D2. The mirror 152 transmits light from the mirror 151 in the second direction D2, and reflects light emitted in the first direction D1 from the semiconductor laser light source 142 in the second direction D2. The second mirror 32 transmits light from the mirror 152 in the second direction D2, and reflects the second beam L2 emitted in the first direction D1 from the second semiconductor laser light source 22 in the second direction D2. The mirrors 32, 151, 152, and 153 are dichroic mirrors.

The mirror 153 transmits light reflected by the sixth mirror 36 in the sixth direction D6, and reflects light emitted in the fifth direction D5 from the semiconductor laser light source 142 in the sixth direction D6. The mirror 154 transmits light from the mirror 153 in the sixth direction D6, and reflects light emitted in the second direction D2 from the semiconductor laser light source 141 in the sixth direction D6. The seventh mirror 37 transmits light from the mirror 154 in the sixth direction D6, and reflects the first beam L1 emitted in the fifth direction D5 from the first semiconductor laser light source 21 in the sixth direction D6. The mirrors 37 and 154 are dichroic mirrors.

The eighth mirror 38 transmits light from the second mirror 32 in the second direction D2, and reflects light from the seventh mirror 37 in the second direction D2. The eighth mirror 38 multiplexes a beam from the second mirror 32 and a beam from the seventh mirror 37.

The light condensing optical system 40 condenses the beams L1 and L5 emitted from the first semiconductor laser light source 21, the beams L2 and L6 emitted from the second semiconductor laser light source 22, a beam emitted from the semiconductor laser light source 141, and a beam emitted from the semiconductor laser light source 142. Therefore, in the laser module 800, it is possible to achieve a higher output as compared to the laser module 700.

Note that the number of semiconductor laser light sources and the number of mirrors are not particularly limited.

### 3. Laser Processing Machine

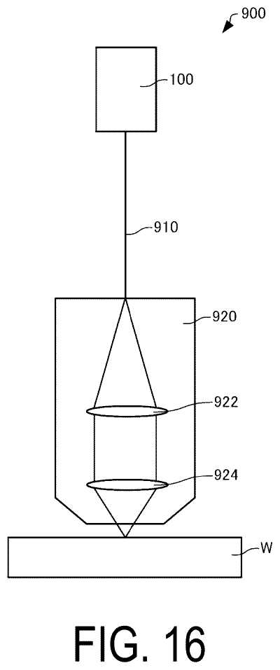

Next, a laser processing machine according to the embodiment will be described with reference to the drawings. FIG. 16 is a diagram schematically illustrating a laser processing machine 900 according to the embodiment.

As illustrated in FIG. 16, the laser processing machine 900 includes, for example, the laser module 100, an optical fiber 910, and a processing head 920.

Light emitted from the laser module 100 is guided to the processing head 920 through the optical fiber 910.

The laser processing machine 900 processes a workpiece W. Specifically, in the laser processing machine 900, the processing head 920 is moved relative to the workpiece W, and light is radiated from the processing head 920 to process the workpiece W. The processing head 920 includes lenses 922 and 924. The lenses 922 and 924 condense light radiated from the optical fiber 910 and guides the light to the workpiece W. A material of the workpiece W is not particularly limited, and may be metal, resin, or a ceramic. Additionally, although not illustrated, the laser processing machine 900 need not include the optical fiber 910, and the laser module 100 may be incorporated in the processing head 920.

Note that uses of the laser processing machine according to the present disclosure are not particularly limited. The laser processing machine according to the present disclosure may be a processing machine for cutting the workpiece W or drilling a hole in the workpiece W. Further, the laser processing machine according to the present disclosure may be, for example, a laser cleaner that removes rust or the like attached to metal by laser light, a laser annealing device that heats a surface of metal or resin with laser light, or a 3D printer.

Further, the laser processing machine according to the present disclosure may include a laser module other than the laser module 100 as long as the laser module is a laser module according to the present disclosure.

The embodiment and the modifications described above are merely examples, and are not intended as limiting. For example, each embodiment and each modification can also be combined together as appropriate.

The present disclosure includes configurations that are substantially identical to the configurations described in the embodiment, for example, configurations with identical functions, methods and results, or with identical advantages and effects. Also, the present disclosure includes configurations obtained by replacing non-essential portions of the configurations described in the embodiment. In addition, the present disclosure also includes configurations that achieve the same effects as the configurations described in the embodiments or configurations that can achieve the same advantages. Further, the present disclosure includes configurations obtained by adding known techniques to the configurations described in the embodiment.

The following contents are derived from the embodiment and the modification examples described above.

An aspect of a laser module includes
a first substrate,
a first semiconductor laser light source provided at the first substrate and configured to emit a first beam in a first direction inclined at a first angle larger than 0° and smaller than 90° with respect to a first perpendicular line of an emission surface,
a second semiconductor laser light source provided at the first substrate and configured to emit a second beam in the first direction,
a first mirror provided parallel to the first perpendicular line and configured to reflect the first beam emitted in the first direction from the first semiconductor laser light source,
a second mirror configured to transmit the first beam reflected by the first mirror in a second direction different from the first direction and reflect the second beam emitted from the second semiconductor laser light source in the second direction, and
a light condensing optical system configured to condense the first beam and the second beam from the second mirror.

This laser module can be reduced in size.

In an aspect of the laser module,
the first beam and the second beam may enter the second mirror as beams different from each other in polarization direction, and
the second mirror may be a polarization beam combiner.

According to this laser module, the first beam and the second beam can be multiplexed at the second mirror.

In an aspect of the laser module,
the first beam and the second beam may be different from each other in wavelength, and
the second mirror may be a dichroic mirror.

According to this laser module, the first beam and the second beam can be multiplexed at the second mirror.

In an aspect of the laser module,
the first semiconductor laser light source and the second semiconductor laser light source may be provided at a first plane of the first substrate.

According to this laser module, temperature characteristics of the first semiconductor laser light source and temperature characteristics of the second semiconductor laser light source can be made more uniform.

In an aspect of the laser module,
a second substrate provided facing the first substrate,
a third semiconductor laser light source provided at the second substrate and configured to emit a third beam in a third direction inclined at a second angle larger than 0° and smaller than 90° with respect to a second perpendicular line of an emission surface,
a fourth semiconductor laser light source provided at the second substrate and configured to emit a fourth beam in the third direction,
a third mirror provided parallel to the second perpendicular line and configured to reflect the third beam emitted in the third direction from the third semiconductor laser light source,
a fourth mirror configured to transmit the third beam reflected by the third mirror in a fourth direction different from the third direction and reflect the fourth beam emitted from the fourth semiconductor laser light source in the fourth direction, and
a fifth mirror provided in an optical path from the second mirror to the light condensing optical system, and configured to reflect the first beam and the second beam from the second mirror in the fourth direction, and transmit the third beam and the fourth beam from the fourth mirror in the fourth direction
may be included, wherein
an emission surface of the first semiconductor laser light source and an emission surface of the third semiconductor laser light source may be parallel to each other, and
the light condensing optical system may condense the first beam, the second beam, the third beam, and the fourth beam from the fifth mirror.

According to this laser module, it is possible to achieve a high output.

In an aspect of the laser module,
the first beam and the second beam may enter the fifth mirror as first polarized beams,
the third beam and the fourth beam may enter the fifth mirror as second polarized beams different from the first polarized beams, and
the fifth mirror may be a polarization beam combiner.

According to this laser module, the first beam, the second beam, the third beam, and the fourth beam can be multiplexed.

In an aspect of the laser module,
the first beam and the second beam may be light having a first wavelength,
the third beam and the fourth beam may be light having a second wavelength different from the first wavelength, and
the fifth mirror may be a dichroic mirror.

According to this laser module, the first beam, the second beam, the third beam, and the fourth beam can be multiplexed.

In an aspect of the laser module,
the third semiconductor laser light source and the fourth semiconductor laser light source may be provided at a second plane of the second substrate.

According to this laser module, temperature characteristics of the third semiconductor laser light source and temperature characteristics of the fourth semiconductor laser light source can be made more uniform.

In an aspect of the laser module,
the first semiconductor laser light source and the second semiconductor laser light source may be different from each other in emission surface position in a direction along the first perpendicular line.

According to this laser module, color aberration of the light condensing optical system can be corrected.
In an aspect of the laser module,
the first semiconductor laser light source and the second semiconductor laser light source may be photonic crystal surface emitting lasers.

According to this laser module, the first semiconductor laser light source can emit the first beam in the first direction inclined at the first angle with respect to the first perpendicular line, and the second semiconductor laser light source can emit the second beam in the first direction inclined at the first angle with respect to the first perpendicular line.

In an aspect of the laser module,
the first semiconductor laser light source may emit a fifth beam in a fifth direction inclined at a third angle symmetrical to the first angle with respect to the first perpendicular line,
the second semiconductor laser light source may emit a sixth beam in the fifth direction,
a sixth mirror that is provided parallel to the first perpendicular line and reflects the sixth beam emitted in the fifth direction from the second semiconductor laser light source,
a seventh mirror that transmits the sixth beam reflected by the sixth mirror in a sixth direction different from the fifth direction and reflects the fifth beam emitted from the first semiconductor laser light source in the sixth direction, and
an eighth mirror that is provided in an optical path from the second mirror to the light condensing optical system, transmits the first beam and the second beam from the second mirror in the second direction, and reflects the fifth beam and the sixth beam from the seventh mirror in the second direction
may be included, and
the light condensing optical system may condense the first beam, the second beam, the fifth beam, and the sixth beam.

According to this laser module, it is possible to achieve a high output.

An aspect of a laser processing machine includes the laser module.

What is claimed is:

1. A laser module, comprising:
a first substrate;
a first semiconductor laser light source provided at the first substrate and configured to emit a first beam in a first direction inclined at a first angle larger than 0° and smaller than 90° with respect to a first perpendicular line of an emission surface;
a second semiconductor laser light source provided at the first substrate and configured to emit a second beam in the first direction;
a first mirror provided parallel to the first perpendicular line and configured to reflect the first beam emitted in the first direction from the first semiconductor laser light source;
a second mirror configured to transmit the first beam reflected by the first mirror in a second direction different from the first direction and reflect the second beam emitted from the second semiconductor laser light source in the second direction; and
a light condensing optical system configured to condense the first beam and the second beam from the second mirror.

2. The laser module according to claim 1, wherein
the first beam and the second beam enter the second mirror as beams different from each other in polarization direction, and
the second mirror is a polarization beam combiner.

3. The laser module according to claim 1, wherein
the first beam and the second beam are different from each other in wavelength, and
the second mirror is a dichroic mirror.

4. The laser module according to claim 1, wherein
the first semiconductor laser light source and the second semiconductor laser light source are provided at a first plane of the first substrate.

5. The laser module according to claim 1, comprising:
a second substrate provided facing the first substrate;
a third semiconductor laser light source provided at the second substrate and configured to emit a third beam in a third direction inclined at a second angle larger than 0° and smaller than 90° with respect to a second perpendicular line of an emission surface;
a fourth semiconductor laser light source provided at the second substrate and configured to emit a fourth beam in the third direction;
a third mirror provided parallel to the second perpendicular line and configured to reflect the third beam emitted in the third direction from the third semiconductor laser light source;
a fourth mirror configured to transmit the third beam reflected by the third mirror in a fourth direction different from the third direction and reflect the fourth beam emitted from the fourth semiconductor laser light source in the fourth direction; and
a fifth mirror provided in an optical path from the second mirror to the light condensing optical system and configured to reflect the first beam and the second beam from the second mirror in the fourth direction, and transmit the third beam and the fourth beam from the fourth mirror in the fourth direction, wherein
an emission surface of the first semiconductor laser light source and an emission surface of the third semiconductor laser light source are parallel to each other, and
the light condensing optical system condenses the first beam, the second beam, the third beam, and the fourth beam from the fifth mirror.

6. The laser module according to claim 5, wherein
the first beam and the second beam enter the fifth mirror as first polarized beams,
the third beam and the fourth beam enter the fifth mirror as second polarized beams different from the first polarized beams, and
the fifth mirror is a polarization beam combiner.

7. The laser module according to claim 5, wherein
the first beam and the second beam are light having a first wavelength,
the third beam and the fourth beam are light having a second wavelength different from the first wavelength, and
the fifth mirror is a dichroic mirror.

8. The laser module according to claim 5, wherein
the third semiconductor laser light source and the fourth semiconductor laser light source are provided at a second plane of the second substrate.

9. The laser module according to claim 3, wherein
the first semiconductor laser light source and the second semiconductor laser light source are different from each other in emission surface position in a direction along the first perpendicular line.

10. The laser module according to claim 1, wherein
the first semiconductor laser light source and the second semiconductor laser light source are photonic crystal surface emitting lasers.

11. The laser module according to claim 10, wherein
the first semiconductor laser light source emits a fifth beam in a fifth direction inclined at a third angle symmetrical to the first angle with respect to the first perpendicular line,
the second semiconductor laser light source emits a sixth beam in the fifth direction,
the laser module includes a sixth mirror that is provided parallel to the first perpendicular line and reflects the sixth beam emitted in the fifth direction from the second semiconductor laser light source,
a seventh mirror that transmits the sixth beam reflected by the sixth mirror in a sixth direction different from the fifth direction and reflects the fifth beam emitted from the first semiconductor laser light source in the sixth direction, and
an eighth mirror that is provided in an optical path from the second mirror to the light condensing optical system, transmits the first beam and the second beam from the second mirror in the second direction, and reflects the fifth beam and the sixth beam from the seventh mirror in the second direction
and
the light condensing optical system condenses the first beam, the second beam, the fifth beam, and the sixth beam.

12. A laser processing machine comprising the laser module according to claim 1.
